(19) United States
(12) Patent Application Publication
(10) Pub. No.: US 2013/0134834 A1
(43) Pub. Date: May 30, 2013

(54) BACKING MEMBER, ULTRASONIC PROBE, AND ULTRASONIC IMAGE DISPLAY APPARATUS

(71) Applicant: GE MEDICAL SYSTEMS GLOBAL TECHNOLOG, Waukesha, WI (US)

(72) Inventors: Yasuo Yoshikawa, Tokyo (JP); Hiroshi Isono, Tokyo (JP)

(73) Assignee: GE MEDICAL SYSTEMS GLOBAL TECHNOLOGY COMPANY, LLC, Waukesha, WI (US)

(21) Appl. No.: 13/687,107

(22) Filed: Nov. 28, 2012

(30) Foreign Application Priority Data
Nov. 28, 2011 (JP) 2011-258659

(51) Int. Cl. H01L 41/053

(52) U.S. Cl. CPC H01L 41/053
USPC 310/341

(57) ABSTRACT

A backing member is provided in an ultrasonic probe on a side of the ultrasonic probe opposite from a transmission direction of an ultrasonic wave to a subject with respect to an ultrasonic vibrator that transmits the ultrasonic wave to the subject. The backing member includes a plate-like backing material, a thermal conductor, and a thermal conductive plate, wherein the thermal conductor and the thermal conductive plate are made of a material having a thermal conductivity higher than a thermal conductivity of the backing material, wherein the thermal conductor is buried in the backing material, and formed to have a columnar shape so as to reach both of two plate surfaces of the backing material, and wherein the thermal conductive plate is provided on at least the plate surface of the backing material that is near the ultrasonic vibrator.

### CROSS REFERENCE TO RELATED APPLICATIONS

This application claims the benefit of Japanese Patent Application No. 2011-258659 filed Nov. 28, 2011, which is hereby incorporated by reference in its entirety.

### BACKGROUND OF THE INVENTION

The present invention relates to a backing member, an ultrasonic probe, and an ultrasonic image display apparatus that can suppress an increase in a surface temperature of the ultrasonic probe.

The ultrasonic probe includes an ultrasonic vibrator, an acoustic matching layer, and a backing member. More specifically, the acoustic matching layer is provided near the subject with respect to the ultrasonic vibrator, while the backing member is provided at the side opposite from the subject (see, for example, JP-A No. 2009-61112). An acoustic lens that is in contact with the subject is provided near the subject with respect to the acoustic matching layer. The ultrasonic vibrator is made of a piezoelectric transducer such as PZT (lead zirconate titanium), wherein voltage is applied to the ultrasonic vibrator for emitting an ultrasonic wave.

The ultrasonic probe includes an ultrasonic vibrator, an acoustic matching layer, and a backing member. More specifically, the acoustic matching layer is provided near the subject with respect to the ultrasonic vibrator, while the backing member is provided at the side reverse to the subject (see, for example, Patent Literature 1). An acoustic lens that is in contact with the subject is provided near the subject with respect to the acoustic matching layer. The ultrasonic vibrator is made of a piezoelectric transducer such as PZT (lead zirconate titanium), wherein voltage is applied to the ultrasonic vibrator for emitting ultrasonic wave.

During the transmission and reception of the ultrasonic wave, heat is generated on the ultrasonic vibrator. Since the backing member has thermal conductivity lower than that of the acoustic matching layer, the heat generated on the ultrasonic vibrator is transmitted to the acoustic matching layer (i.e., to the subject, not to the backing member). Therefore, when the ultrasonic probe is continuously used, the temperature of the surface of the acoustic lens increases. Accordingly, the output of the ultrasonic wave from the ultrasonic vibrator is restricted in order to prevent the increase in the surface temperature of the acoustic lens during the transmission and reception of the ultrasonic wave. From above, an ultrasonic probe has been demanded that can release the heat, which is generated on the ultrasonic vibrator, to the side opposite from the surface of the ultrasonic probe.

### BRIEF DESCRIPTION OF THE INVENTION

In one aspect, a backing member is provided in an ultrasonic probe on a side opposite from a transmission direction of ultrasonic wave to a subject with respect to an ultrasonic vibrator that transmits the ultrasonic wave to the subject. The backing member includes a plate-like backing material, and a thermal conductor and a thermal conductive plate that are made of a material having thermal conductivity higher than that of the backing material, wherein the thermal conductor is buried in the backing material, and formed to have a columnar shape so as to reach both plate surfaces of the backing material, and the thermal conductive plate is provided on at least one surface near the ultrasonic vibrator, out of the plate surfaces of the backing material. Therefore, the heat generated from the ultrasonic vibrator can be released to the side reverse to the surface of the ultrasonic probe through the thermal conductive plate and the thermal conductor. Accordingly, the increase in the surface temperature of the ultrasonic probe can be prevented. An ultrasonic probe including a backing layer having the backing member, and an ultrasonic image display apparatus including the ultrasonic probe are also provided.

In another aspect, the thermal conductor is buried as being dispersed in the backing material whereby the deterioration in the effect of the backing layer as an acoustic absorbing material can be prevented.

### BRIEF DESCRIPTION OF THE DRAWINGS

FIG. 1 is a block diagram illustrating one example of an ultrasonic diagnostic apparatus according to a first embodiment.

FIG. 2 is a perspective view illustrating an appearance of an ultrasonic probe according to the first embodiment.

FIG. 3 is a perspective view illustrating an appearance of only a functional device unit of the ultrasonic probe illustrated in FIG. 2.

FIG. 4 is a sectional view taken along a line x-z of the functional device unit of the ultrasonic probe illustrated in FIG. 2.

FIG. 5 is a plan view illustrating a part of a backing member into which thermal conductors are buried.

FIG. 6 is a view for describing an emission of ultrasonic wave.

FIG. 7 is a sectional view taken along a line x-z of a functional device unit of an ultrasonic probe according to a modification of the first embodiment.

FIG. 8 is a perspective view illustrating an appearance of only a functional device unit of an ultrasonic probe according to a second embodiment.

FIG. 9 is a sectional view taken along a line x-z of the functional device unit of the ultrasonic probe illustrated in FIG. 8.

FIG. 10 is a sectional view taken along a line x-z of a functional device unit of an ultrasonic probe according to a modification of the second embodiment.

FIG. 11 is an end view illustrating a part of a curved backing member.

FIG. 12 is a plan view illustrating a part of another backing member into which thermal conductors are buried.

FIG. 13 is a plan view illustrating a part of another backing member into which thermal conductors are buried.

### DETAILED DESCRIPTION OF THE INVENTION

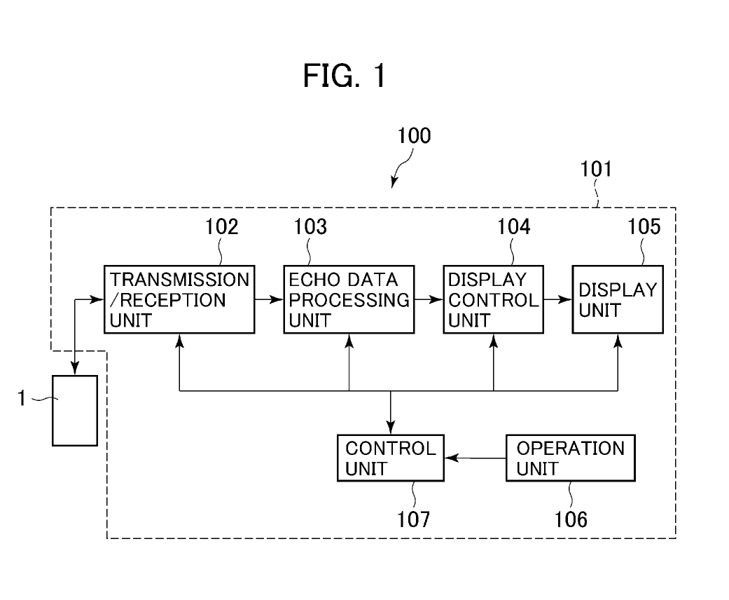

Exemplary embodiments will be described below. An ultrasonic diagnostic apparatus illustrated in FIG. 1 transmits and receives ultrasonic wave to and from a patient (also referred to herein as a subject) so as to display an ultrasonic image of the patient, and it is one example of an ultrasonic image display apparatus. The ultrasonic diagnostic apparatus 100 includes an ultrasonic probe 1, and an apparatus body 101 to which the ultrasonic prove 1 is connected.

The apparatus body 101 includes a transmission/reception unit 102, an echo data processing unit 103, a display control unit 104, a display unit 105, an operation unit 106, and a control unit 107.

The transmission/reception unit 102 supplies an electric signal, which is for transmitting an ultrasonic wave under a predetermined scan condition from the ultrasonic probe 1, to the ultrasonic probe 1 based upon a control signal from the control unit 107. The transmission/reception unit 102 also performs a signal processing, such as an A/D conversion or phasing/adding process, to an echo signal received by the ultrasonic probe 1.

The echo data processing unit 103 performs a process for generating an ultrasonic image to echo data outputted from the transmission/reception unit 102. For example, the echo data processing unit 103 performs a B-mode process, such as a logarithmic compression process or envelope demodulation process, thereby generating B-mode data.

The display control unit 104 performs a scan conversion to the data inputted from the echo data processing unit 103 by use of a scan converter, so as to generate ultrasonic image data, and allows the display unit 105 to display the ultrasonic image based upon the ultrasonic image data. The display control unit 104 generates B-mode image data based upon the B-mode data, and displays the B-mode image on the display unit 105, for example.

The display unit 105 is made of an LCD (Liquid Crystal Display) or CRT (Cathode Ray Tube), for example. The operation unit 106 includes a switch, a keyboard, and a pointing device (not illustrated) used by an operator to input an instruction or information.

The control unit 107 is configured to include a CPU (Central Processing Unit), although not particularly illustrated. The control unit 107 reads a control program stored in a storage unit, not illustrated, and executes functions of respective units in the ultrasonic diagnostic apparatus 100.

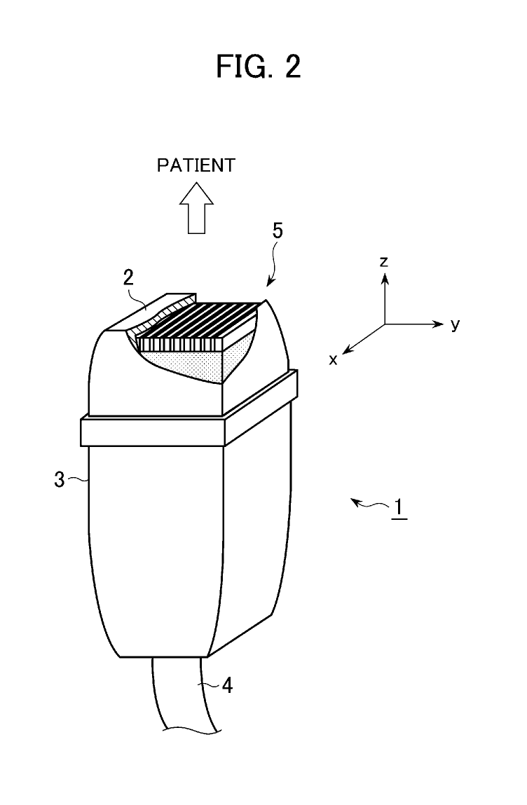

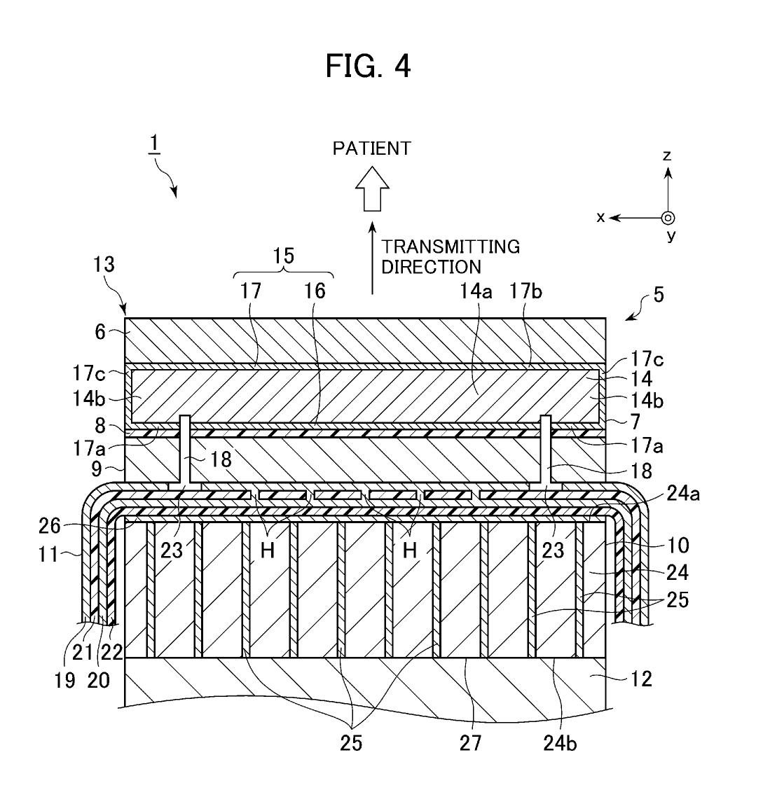

The ultrasonic probe 1 will be described with reference to FIGS. 2 to 6. The ultrasonic probe 1 performs an ultrasonic scan on a patient. The ultrasonic probe 1 also receives an ultrasonic echo signal.

The ultrasonic probe 1 has an acoustic lens unit 2 at its leading end. The ultrasonic probe 1 includes a probe housing 3, and a connection cable 4 by which the ultrasonic probe 1 is connected to the apparatus body 101. It is to be noted that FIG. 2 illustrates a sector probe.

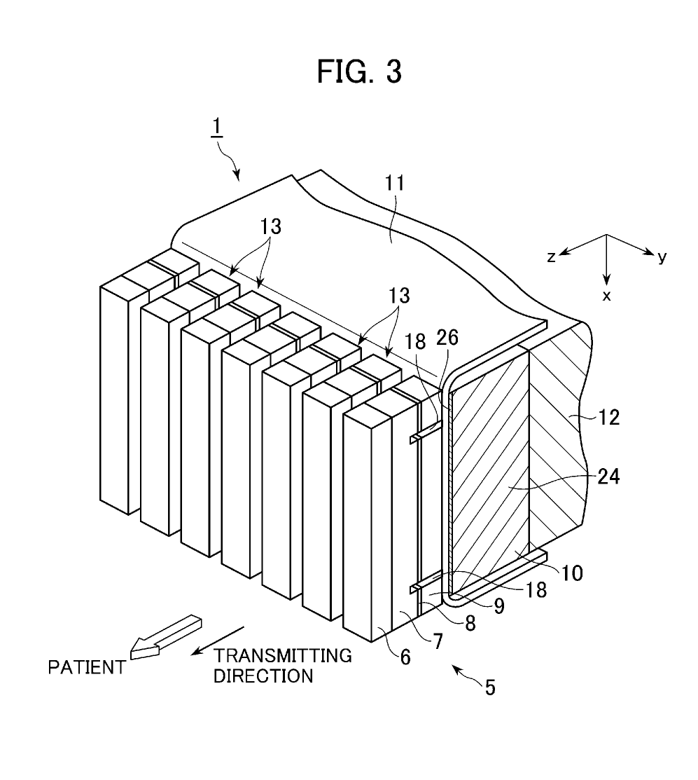

A functional device unit 5 is provided in the probe housing 3. The functional device unit 5 will be described in detail with reference to FIGS. 3 to 5. The functional device unit 5 includes an acoustic matching layer 6, an ultrasonic vibrator 7, an adhesion layer 8, a reflection layer 9, a backing layer 10, a flexible substrate 11, and a support body 12. The acoustic matching layer 6, the ultrasonic vibrator 7, and the reflection layer 9, each having a shape of rectangular solid that is long in an x-axis direction, are stacked in a z-axis direction that is along the irradiation direction of the ultrasonic wave, thereby forming a stacked body 13. Plural stacked bodies 13 are arranged in a y-axis direction.

The acoustic matching layer 6 is bonded to a surface of the ultrasonic vibrator 7 on the emission side of the ultrasonic wave (the adhesion layer is not illustrated). The acoustic matching layer 6 has an acoustic impedance intermediate between that of the ultrasonic vibrator 7 and the acoustic lens unit 2. The acoustic matching layer 6 has a thickness of about one quarter of the center frequency of the transmitting ultrasonic wave, and it inhibits the reflection on a boundary surface having different acoustic impedance. Although only one acoustic matching layer 6 is shown in the present embodiment, two or more acoustic matching layers 6 may be formed.

The piezoelectric vibrator 7 includes a piezoelectric member 14 and a conductive layer 15 formed on the surface of the piezoelectric member 14. The piezoelectric member 14 is PZT, or the like. The conductive layer 15 is formed on the surface of the piezoelectric member 14 by a sputtering.

The conductive layer 15 has a signal electrode 16 and a ground electrode 17. The signal electrode 16 is formed on the surface of a portion 14a between later-described boreholes 18 and 18 on the piezoelectric member 14. The ground electrode 17 includes first portions 17a and 17a formed on the same surface as the signal electrode 16 across the boreholes 18 and 18 on end portions 14b and 14b of the piezoelectric member 14, a second portion 17b formed on the surface of the piezoelectric member 14 opposite from the surface on which the first portions 17a and 17a are formed, and third portions 17c and 17c formed on the side faces of the ultrasonic vibrator 7, having the rectangular solid shape, between the first portions 17a and 17a and the second portion 17b. The signal electrode 16 is formed to be sandwiched between the first portions 17a and 17a of the ground electrode 17, wherein both electrodes 16 and 17 are electrically isolated by the boreholes 18 and 18.

The total thickness of the ultrasonic vibrator 7 and the adhesion layer 8 is about a quarter of the center frequency of the ultrasonic wave generated by the vibration of the ultrasonic vibrator 7. Specifically, the thickness of the ultrasonic vibrator 7 is about hundreds of micrometers.

The reflection layer 9 is bonded to the surface of the ultrasonic vibrator 7 opposite to the emission direction of the ultrasonic wave to the patient (reverse side of the acoustic matching layer 6) with the adhesion layer 8 made of an epoxy resin adhesion. The reflection layer 9 is bonded to the signal electrode 16 and the first portions 17a and 17a.

The surface of the reflection layer 9 near the ultrasonic vibrator 7 undergoes a mirror polishing. The surfaces of the signal electrode 16 and the first portions 17a and 17a on the ultrasonic vibrator 7 also undergo a mirror polishing. With this process, the surface of the reflection layer 9 near the ultrasonic vibrator 7 and the surfaces of the signal electrode 16 and the first portions 17a and 17a on the ultrasonic vibrator 7 only have irregularities of several micrometers. Therefore, the thickness of the adhesion layer 8 can be set to have a thickness of several micrometers, whereby the adhesion layer 8 can be formed as thin as possible to have a uniform thickness.

As described above, the thickness of the adhesion layer 8 is almost the same as the irregularities on the surface of the signal electrode 16, the irregularities on the surface of the first portions 17a and 17a, and the irregularities on the surface of the reflection layer 9. Therefore, although the adhesion layer 8 is an insulating member containing the epoxy resin adhesive, it is locally in contact with the signal electrode 16, the first portions 17a and 17a, and the reflection layer 9 on the irregularities on their surfaces, whereby electric conduction is established.

The reflection layer 9 functions as a fixed end that reflects the ultrasonic wave, which is generated toward the reflection layer 9 by the vibration of the ultrasonic vibrator 7, to the direction of the patient. The ultrasonic wave reflected on the reflection layer 9 increases ultrasonic power incident on the patient. The reflection layer 9 is one example of a reflection layer according to one embodiment. The reflection layer 9 is made of a material having acoustic impedance larger than that of the piezoelectric member 14 in order to reflect the ultrasonic wave generated from the ultrasonic vibrator 7. For example, the reflection layer 9 is made of tungsten.

Since the tungsten forming the reflection layer 9 has conductivity, the reflection layer 9 has a function of electrically connecting later-described first copper foil layer 19 and a second copper foil layer 20 of the flexible substrate 11 and the signal electrode 16 and the ground electrode 17 of the ultrasonic vibrator 7. Thus, the voltage supplied from the first copper foil layer 19 and the second copper foil layer 20 is applied to the ultrasonic vibrator 7 through the reflection layer 9.

The boreholes 18 and 18 are formed on both ends of the reflection layer 9, the adhesion layer 8, and the ultrasonic vibrator 7 in the longitudinal direction. The boreholes 18 and 18 are formed by a cutting process by use of a diamond grindstone from the reflection layer 9, after the ultrasonic vibrator 7 and the reflection layer 9 are bonded to the adhesion layer 8.

The flexible substrate 11 is bonded between the surface of the reflection layer 9 opposite from the surface where the ultrasonic vibrator 7 is bonded and the backing layer 10 (the adhesion layer is not illustrated). The flexible substrate 11 is extended along the side face of the backing layer 10 in the widthwise direction, and is connected to the connection cable 4 (the connection structure is not illustrated).

The structure of the flexible substrate 11 will be described. The flexible substrate 11 includes four layers, which are the first copper foil layer 19, the second copper foil layer 20, a first polyimide membrane layer 21, and a second polyimide membrane layer 22. The first copper foil layer 19 and the second copper foil layer 20 are electrically isolated from each other by the first polyimide layer 21. The first copper foil layer 19 is formed to be located on both ends of the reflection layer 9 from the boreholes 18 and 18 as being bonded to the reflection layer 9. The second copper foil layer 20 is stacked between the first polyimide membrane layer 21 and the second polyimide membrane layer 22, and is present on the same surface of the first copper foil layer 19, via through holes H, on the central part of the reflection layer 9 between the boreholes 18 and 18. The first copper foil layer 19 and the second copper foil layer 20, which are present on the same surface, are insulated from each other by a separation channel 23. The separation channel 23 is formed to be located on the boreholes 18 and 18 in a state in which the reflection layer 9 is bonded to the flexible substrate 11. With this structure, the first copper foil layer 19 is electrically connected to the ends of the reflection layer 9, having conductivity, from the boreholes 18 and 18, while the second copper foil layer 20 is electrically connected to the middle portion of the reflection layer 9 between the boreholes 18 and 18. Therefore, the first copper foil layer 19 is electrically connected to the first portions 17a and 17a of the ground electrode 17 on the ultrasonic vibrator 7 through the reflection layer 9, while the second copper foil layer 20 is electrically connected to the signal electrode 16 of the ultrasonic vibrator 7 through the reflection layer 9.

The first copper foil layer 19 connected to the ground electrode 17 is formed all over the front surface of the flexible substrate 11, whereby the conduction of the ground electrode 17 of all ultrasonic vibrators 7 arranged in the y axis direction is established. On the other hand, the second copper foil layer 20 is divided into plural parts in the y axis direction by copper foil dividing channels, not illustrated, and includes plural copper foil patterns, not illustrated, formed in the flexible substrate 11. The copper foil pattern is formed for each of plural stacked bodies 13 arranged in the y axis direction.

The backing layer 10 is bonded to the flexible substrate 11 on the surface opposite from the reflection layer 9, or the backing layer 10 is directly formed on the back surface of the flexible substrate 11, in order to hold the flexible substrate 11. The backing layer 10 is one example of a backing layer according to an embodiment.

The backing layer 10 includes a backing member 27 made of a backing material 24, thermal conductors 25, and a thermal conductive plate 26. The backing member 27 is one example of a backing member according to one embodiment.

The backing material 24 is made of an epoxy resin formed by dispersing and solidifying metal powders, for example. The thermal conductor 25 and the thermal conductive plate 26 are made of a material having thermal conductivity higher than that of the backing material 24 (e.g., it may be made of a metal). With this structure, the thermal resistance of the backing layer 10 is lower than that of a conventional backing layer.

It is only necessary that the thermal conductor 25 and the thermal conductive plate 26 are made of a material having thermal conductivity hundreds or even thousands of times the thermal conductivity of the backing material 24, and it is not limited to the metal. For example, the thermal conductor 25 and the thermal conductive plate 26 may be made of carbon.

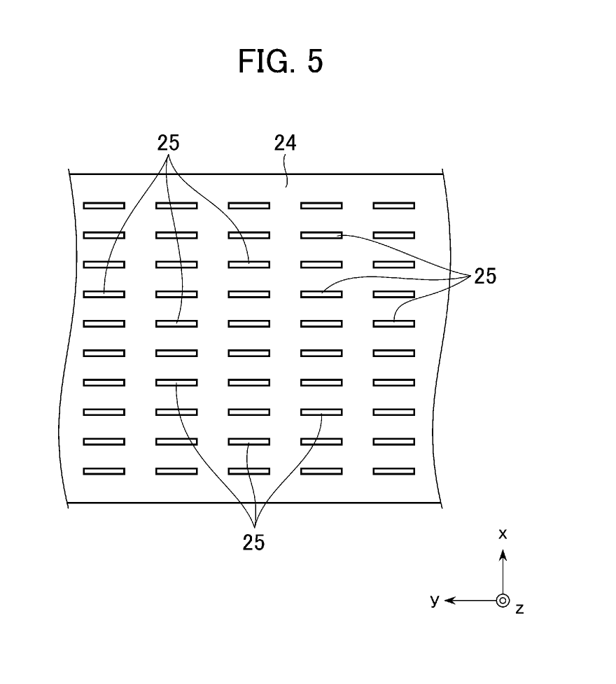

The backing material 24 is formed into a plate-like shape. The thermal conductors 25 are buried in the backing material 24. The thermal conductor 25 is formed to have a columnar shape in order to reach both surfaces of the backing material 24. The thermal conductors 25 are formed to be dispersed in a two-dimensional manner as illustrated in FIG. 5. In the present embodiment, the thermal conductors 25 are arranged in the x direction and y direction with a predetermined space.

The thermal conductor 25 is formed to have a rectangular shape as viewed in a plane, wherein the longitudinal direction directs to the y axis direction. The thermal conductor 25 is buried in the backing material 24 by being inserted into a hole formed on the backing material 24, for example. The method of mounting the thermal conductor 25 to the backing material 24 is not limited thereto.

The thermal conductive plate 26 is bonded to the surface 24a of the backing material 24. The plate surface 24a is one example of one surface of a backing material according to one embodiment. The thickness of the thermal conductive plate 26 is 10% or less of the wavelength of the center frequency of the ultrasonic wave transmitted from the ultrasonic vibrator 7 in one embodiment. The reason will be described below. Most of the ultrasonic wave emitted toward the reflection layer 9 (toward the side opposite from the patient) from the ultrasonic vibrator 7 is reflected on the reflection layer 9 toward the patient. However, the ultrasonic wave with a low frequency transmits the reflection layer 9 to reach the backing material 24, and is absorbed by the backing material 24.

When the thickness of the thermal conductive plate 26 is too large, the ultrasonic wave passing through the reflection layer 9 might be reflected on the thermal conductive plate 26 before it is absorbed by the backing material 24. In view of this, the thermal conductive plate 26 is formed to have the thickness described above, which can prevent the reflection of the ultrasonic wave on the thermal conductive plate 26.

The backing layer 10 is bonded to the support body 12 with an adhesive (the adhesive is not illustrated). The support body 12 is made of a metal, and forms a part of the probe housing 3, for example. The support body 12 is one example of a metal body according to an embodiment.

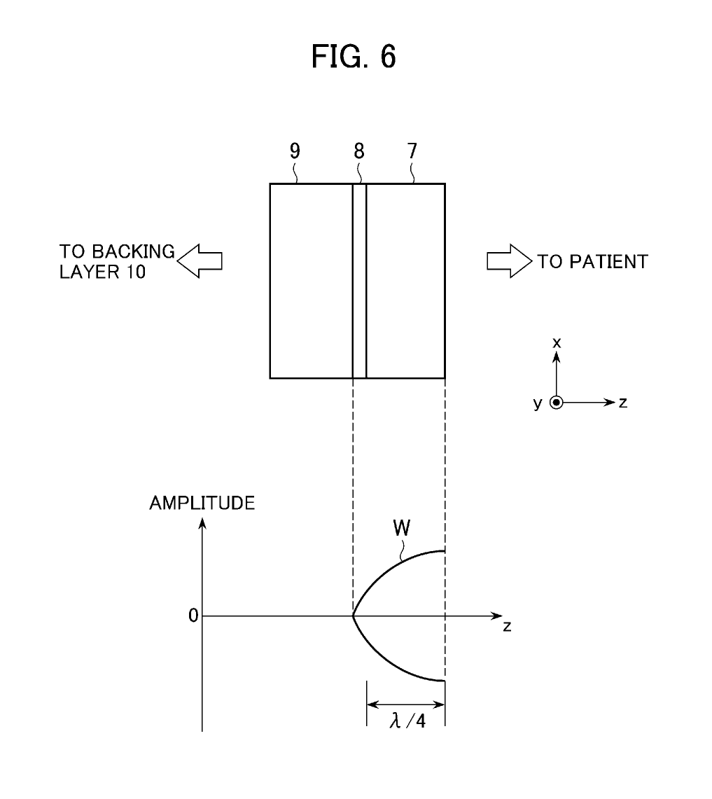

The operation of the functional device unit 5 in the ultrasonic probe 1 in the present embodiment will be described. When voltage is applied between the signal electrode 16 and the ground electrode 17, the ultrasonic vibrator 7 excites resonance vibration. The patient side has a low acoustic impedance composed of the acoustic matching layer 6, and the side of the backing layer 10 that is opposite from the patient is has a high acoustic impedance composed of the reflection layer 9. Therefore, as illustrated in FIG. 6, the resonance vibration forms a standing wave W wherein the side of the patient serves as a free end, and the reflection layer 9 serves as a fixed end.

A coordinate position on the z axis illustrated in the lower part of FIG. 6 corresponds to the position of the ultrasonic vibrator 7 and the reflection layer 9, illustrated in FIG. 6, in the z axis direction.

FIG. 6 illustrates the standing wave W whose amplitude becomes the maximum on the surface of the ultrasonic vibrator 7 near the patient, and whose amplitude becomes zero on the surface of the reflection layer 9 near the ultrasonic vibrator 7. The reflection layer 9 functions as the fixed end. As described above, on the ultrasonic vibrator 7, the standing wave W is generated, wherein the thickness of the ultrasonic vibrator 7 in the z axis direction is set as 1/4 wavelength in the resonance state.

Since the adhesion layer 8 is uniformly thin as described above, there is no chance that the adhesion layer 8 deteriorates the function of the reflection layer 9 as the fixed end.

The heat of the ultrasonic vibrator 7 generated during the emission of the ultrasonic wave is transferred to the reflection layer 9 and the flexible substrate 11 to reach the backing layer 10. The heat reaching the backing layer 10 is transferred to the thermal conductive plate 26 and the thermal conductors 25 to reach the metallic support body 12. Accordingly, the heat from the ultrasonic vibrator 7 can be released to the side opposite from the acoustic lens 2, whereby the temperature rise of the acoustic lens unit 2 can be prevented.

The thermal conductive plate 26 is provided on the surface of the backing layer 10 with which the flexible substrate 11 is in contact, and the plate surface 24a is all covered by a material having thermal conductivity higher than that of the backing material 24. Therefore, the heat is efficiently transferred from the flexible substrate 11 to the backing layer 10.

Although the thermal conductors 25 are buried in the backing material 24, the thermal conductors 25 are dispersed to have a predetermined space in the x direction and in the y direction. Therefore, the backing layer 10 can exhibit a function as an acoustic absorbing material.

Even if the thermal conductive layer 25 made of a metal is formed on the surface of the backing layer 10, the ultrasonic wave transmitted from the ultrasonic vibrator 7 to the side opposite from the patient is reflected on the reflection layer 9, thereby not causing an adverse effect from the viewpoint of an acoustic condition.

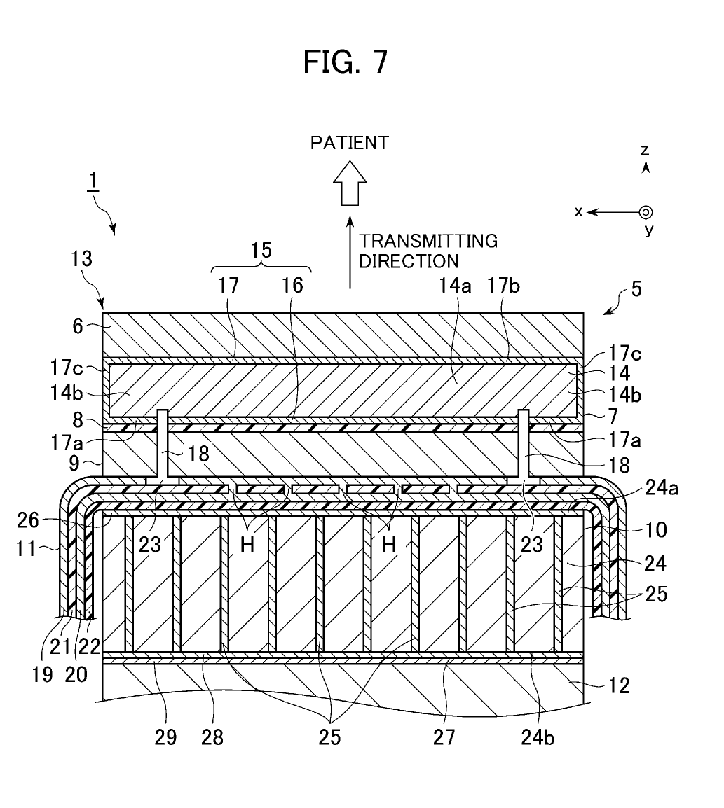

A modification of the first embodiment will next be described with reference to FIG. 7. In this modification, a thermal conductive plate 28 is also provided on the plate surface 24b of the backing material 24. Like the thermal conductive plate 26, the thermal conductive plate 28 is also made of a material having thermal conductivity higher than that of the backing material 24, such as a metal or carbon. The plate surface 24b is one example of other surface of the backing material according to one embodiment.

The backing layer 10 is fixed to the support body 12 with an adhesive sheet layer 29. Even if a layer made of a material having thermal resistance higher than that of metal is interposed between the backing layer 10 and the support body 12, the heat can efficiently be transferred from the backing layer 10 to the support body 12, since the thermal conductive plate 28 is provided all over the plate surface 24b that is in contact with the support body 12.

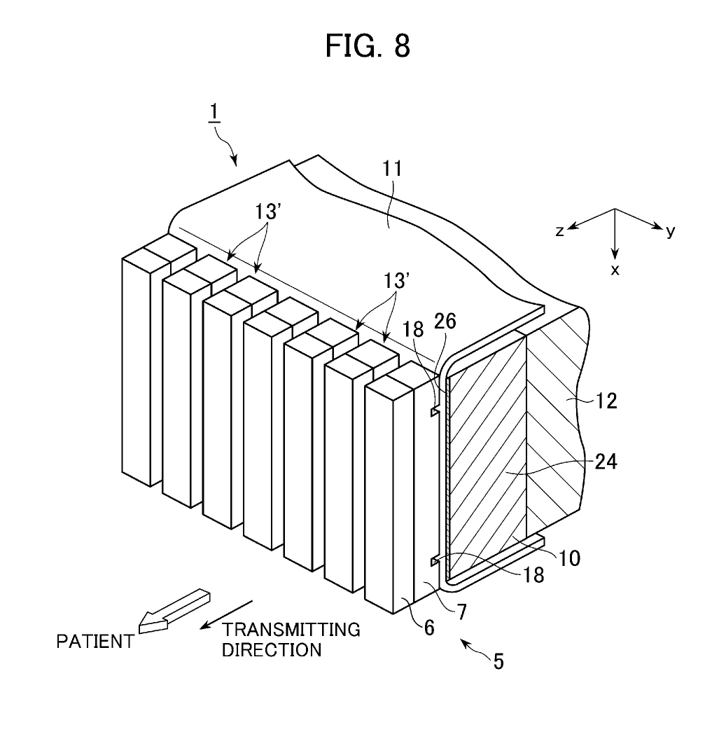

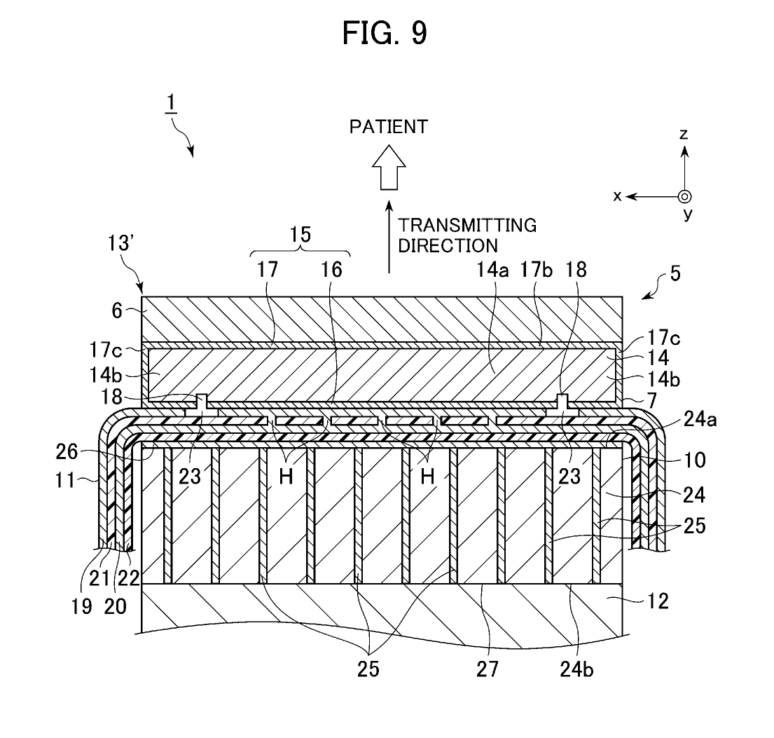

A second embodiment will next be described with reference to FIGS. 8 and 9. The components same as those in the first embodiment are identified by same numerals.

In the ultrasonic probe 1 according to the present embodiment, a stacked body 13′ does not have the reflection layer 9, but only has the acoustic matching layer 6 and the ultrasonic vibrator 7.

Even in the ultrasonic probe 1 according to the present embodiment, the backing layer 10 has the same configuration as in the first embodiment, whereby the temperature rise of the acoustic lens unit 2 can be prevented as in the ultrasonic probe 1 according to the first embodiment.

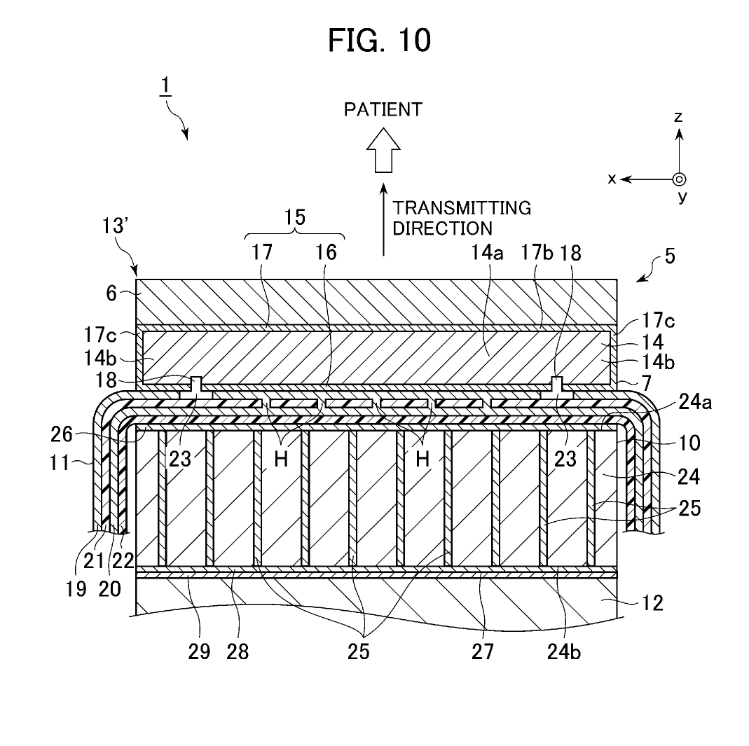

A modification of the second embodiment will be described with reference to FIG. 10. In this modification, the thermal conductive plate 28 is also provided on the plate surface 24b of the backing material 24, as in the modification of the first embodiment. The backing layer 10 is fixed to the support body 12 by the adhesive sheet layer 29. Since the thermal conductive plate 28 is also provided on the plate surface 24b, the heat can efficiently be transferred to the support body 12 as in the modification of the first embodiment.

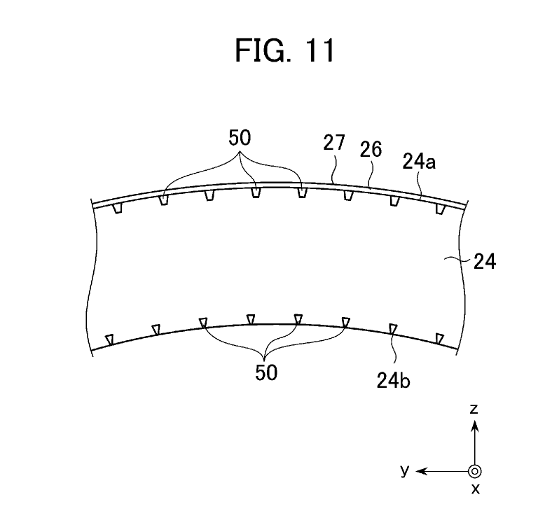

The present invention has been described above with reference to exemplary embodiments. It will be obvious that various modifications are possible without departing from the scope of the present invention. For example, the ultrasonic probe 1 may be a convex probe or linear probe. When the ultrasonic probe 1 is a convex probe, the backing layer 10 is formed by bending the backing member 27 to project in the z axis direction as illustrated in FIG. 11. In this case, in order to easily bend the backing member 27, slits 50 formed along the x axis direction may be formed on the plate surfaces 24a and 24b of the backing material 24. The number of the thermal conductors 25 (not illustrated in FIG. 11) in the direction of the arrangement of ultrasonic vibrator 7 (in the y axis direction) may be equal to the number of the ultrasonic vibrators 7. This structure can easily bend the backing member 27. There is a gap between the thermal conductors 25 on the backing member 27 in the y axis direction, whereby the backing member 27 can easily be bent.

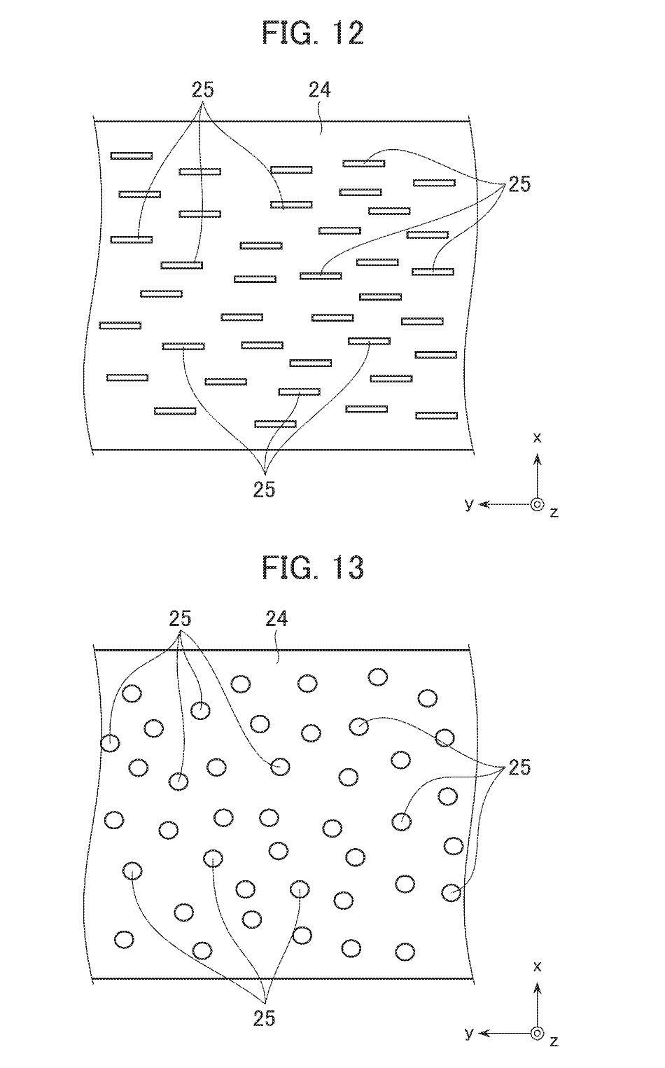

In the above embodiments, the plural thermal conductors 25 are buried in the backing material 24 so as to be arranged in the x direction and in the y direction. However, the arrangement of the thermal conductors 25 is not limited thereto. It is only necessary that the thermal conductors 25 are buried as being dispersed in the backing material 24. For example, the thermal conductors 25 may be arranged sparsely as illustrated in FIG. 12.

The thermal conductor 25 is not limited to have the rectangular shape viewed in a plane as in the above embodiments. For example, the thermal conductor 25 may have a circular shape viewed in a plane as illustrated in FIG. 13.

1. A backing member provided in an ultrasonic probe on a side to of the ultrasonic probe opposite from a transmission direction of an ultrasonic wave to a subject with respect to an ultrasonic vibrator that transmits the ultrasonic wave to the subject, the backing member comprising:
a plate-like backing and material;
a thermal conductor;p and
a thermal conductive plate, wherein the thermal conductor and the thermal conductive plate are made of a material having a thermal conductivity higher than a thermal conductivity of the backing material, wherein the thermal conductor is buried in the backing material, and formed to have a columnar shape so as to reach both of two plate surfaces of the backing material, and wherein the thermal conductive plate is provided on at least the plate surface of the backing material that is near the ultrasonic vibrator.

2. The backing member according to claim 1, wherein the thermal conductor is dispersed in the backing material.

3. The backing member according to claim 1, wherein a thickness of the thermal conductive plate is 10% or less of a wavelength at center frequency of the ultrasonic wave transmitted from the ultrasonic vibrator.

4. The backing member according to claim 2, wherein a thickness of the thermal conductive plate is 10% or less of a wavelength at center frequency of the ultrasonic wave transmitted from the ultrasonic vibrator.

5. An ultrasonic probe comprising a backing layer including the backing member according to claim 1.

6. An ultrasonic probe comprising a backing layer including the backing member according to claim 2.

7. An ultrasonic probe comprising a backing layer including the backing member according to claim 3.

8. An ultrasonic probe comprising a backing layer including the backing member according to claim 4.

9. The ultrasonic probe according to claim 5, further comprising a metal body in contact with the plate surface of the backing layer opposite from the plate surface near the ultrasonic vibrator.

10. The ultrasonic probe according to claim 6, further comprising a metal body in contact with the plate surface of the backing layer opposite from the plate surface near the ultrasonic vibrator.

11. The ultrasonic probe according to claim 7, further comprising a metal body in contact with the plate surface of the backing layer opposite from the plate surface near the ultrasonic vibrator.

12. The ultrasonic probe according to claim 8, further comprising a metal body in contact with the plate surface of the backing layer opposite from the plate surface near the ultrasonic vibrator.

13. The ultrasonic probe according to claim 5, wherein a thermal conductive plate made of a material having thermal conductivity higher than that of the backing material is provided on the plate surface of the backing material that is opposite from the plate surface near the ultrasonic vibrator.

14. The ultrasonic probe according to claim 6, wherein an additional thermal conductive plate made of a material having thermal conductivity higher than that of the backing material is provided on the plate surface of the backing material that is opposite from the plate surface near the ultrasonic vibrator.

15. The ultrasonic probe according to claim 7, wherein an additional thermal conductive plate made of a material having thermal conductivity higher than that of the backing material is provided on the plate surface of the backing material that is opposite from the plate surface near the ultrasonic vibrator.

16. The ultrasonic probe according to claim 8, wherein an additional thermal conductive plate made of a material having thermal conductivity higher than that of the backing material is provided on the plate surface of the backing material that is opposite from the plate surface near the ultrasonic vibrator.

17. The ultrasonic probe according to claim 5, comprising a reflection layer provided between the ultrasonic vibrator and the backing layer, the reflection layer configured to reflect the ultrasonic wave transmitted from the ultrasonic vibrator.

18. The ultrasonic probe according to claim 17, wherein the reflection layer has a higher acoustic impedance than the ultrasonic vibrator and functions as a fixed end for reflecting the ultrasonic wave transmitted from the ultrasonic vibrator.

19. The ultrasonic probe according to claim 5, wherein the thermal conductor and the thermal conductive plate are each made of one of a metal or carbon.

20. An ultrasonic image display apparatus comprising the ultrasonic probe according to claim 5.
